(19) United States
(12) Patent Application Publication
(10) Pub. No.: US 2024/0142806 A1
(43) Pub. Date: May 2, 2024

(54) OPTOELECTRONIC DEVICE

(71) Applicant: STMicroelectronics (Crolles 2) SAS, Crolles (FR)

(72) Inventor: Arthur ARNAUD, La Tronche (FR)

(73) Assignee: STMicroelectronics (Crolles 2) SAS, Crolles (FR)

(21) Appl. No.: 18/383,266

(22) Filed: Oct. 24, 2023

(30) Foreign Application Priority Data
Oct. 31, 2022 (FR) 2211351

(51) Int. Cl. G02F 1/01; B82Y 20/00

(52) U.S. Cl. CPC G02F 1/0126; B82Y 20/00

(57) ABSTRACT

A device includes a first pixel, based on quantum dots, configured to deliver event-based data for generating an event-based image, and second pixels, each second pixel based on quantum dots, configured to deliver light intensity data for generating a light intensity image.

### PRIORITY CLAIM

This application claims the priority benefit of French Application for Patent No. 2211351, filed on Oct. 31, 2022, the content of which is hereby incorporated by reference in its entirety to the maximum extent allowable by law.

### TECHNICAL FIELD

The present disclosure generally concerns electronic devices and, in particular, optoelectronic devices.

### BACKGROUND

Event-based cameras, such as standard cameras, comprise a plurality of pixels, each pixel being configured to deliver a value corresponding to a location in an observed scene. However, conversely to a standard camera, that is, a camera having each of its pixel configured to periodically deliver a light intensity value corresponding to the location, an event-based camera is configured to deliver an information indicating a modification of the light intensity. Event-based cameras are thus configured to deliver an event-based image of a scene. Standard cameras are thus configured to deliver a light intensity image of a scene. Thus, a standard camera is a synchronous camera enabling to obtain at a frame frequency a succession of images comprising as many intensity values as there are pixels. An event-based camera is a synchronous or asynchronous camera delivering, for each pixel, information indicating the luminosity change of the corresponding location in the scene. When the scene is motionless, a standard camera keeps on delivering, periodically, all the intensity values, while an event-based camera delivers no value, indicating the absence of change.

There is a need in the art to overcome all or part of the disadvantages of known optoelectronic devices.

### SUMMARY

An embodiment provides a device configured to generate an event-based image comprising at least one first pixel based on quantum dots configured to deliver event-based data.

Another embodiment provides a method of controlling a device comprising at least one first pixel based on quantum dots, comprising the generation of an event-based image.

According to an embodiment, each first pixel comprises a first region of a quantum dot layer coupled to a second region of a substrate comprising a circuit for controlling the first pixel by a conductive via.

According to an embodiment, the second region comprises a portion located in front of the first region and a portion which is not in front of the first region.

According to an embodiment, the device is configured to, further, generate a light intensity image, comprising at least one second pixel based on quantum dots configured to deliver light intensity data.

According to an embodiment, each second pixel comprises a third region of a quantum dot layer coupled to a fourth region of a substrate comprising a circuit for controlling the second pixel by a conductive via.

According to an embodiment, the third region comprises a portion located in front of the fourth region and a portion which is not in front of the fourth region.

According to an embodiment, each first pixel is surrounded by second pixels.

According to an embodiment, the device comprises an array of assemblies of pixels, each assembly comprising one first pixel and eight second pixels surrounding the first pixel.

According to an embodiment, the device comprises an array of assemblies of pixels, each assembly comprising one first pixel and three second pixels, arranged in an array.

According to an embodiment, the first and third regions all have identical dimensions.

According to an embodiment, the device comprises an array of assemblies of pixels, each assembly comprising one first pixel and four second pixels, each second pixel having the shape of a rectangle with a beveled corner, the beveled corners of the second pixels defining the first region of the first pixel.

According to an embodiment, the device comprises an array of assemblies of pixels, each assembly comprising one first pixel and four second pixels, the first region of the first pixel having the shape of a cross separating from one another the third regions of the second pixels.

According to an embodiment, the first pixels are covered with an infrared filter and each second pixel is covered with a filter letting through a visible wavelength range.

According to an embodiment, the first pixels generate an event-based image independently from the generation of a light intensity image by the second pixels.

According to an embodiment, the generation of an event-based data element by a first pixel triggers the generation of light intensity data by at least one second pixel.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows an example of a pixel of an event-based camera;

FIG. 2 shows an embodiment of a pixel of an event-based camera;

FIGS. 3A and 3B show embodiments of pixels;

FIG. 4A shows, in a perspective view, an embodiment of a pixel assembly;

FIG. 4B shows a top view of a portion of the embodiment of FIG. 4A;

FIG. 4C shows a top view of a device comprising the pixel assembly of FIG. 4A;

FIG. 5A shows, in a perspective view, another embodiment of a pixel assembly;

FIG. 5B shows a top view of a portion of the embodiment of FIG. 5A;

FIG. 5C shows a top view of a device comprising the pixel assembly of FIG. 5A;

FIG. 6A shows, in a perspective view, another embodiment of a pixel assembly;

FIG. 6B shows a top view of a portion of the embodiment of FIG. 6A;

FIG. 6C shows a top view of a device comprising the pixel assembly of FIG. 6A;

FIG. 7A shows, in a perspective view, another embodiment of a pixel assembly;

FIG. 7B shows a top view of a portion of the embodiment of FIG. 7A;

FIG. 7C shows a top view of a device comprising the pixel assembly of FIG. 7A;

FIG. 8 shows an embodiment of an example of arrangement of filters;

FIG. 9 shows another embodiment of an example of arrangement of filters;

FIG. 10 shows another embodiment of an example of arrangement of filters;

FIG. 11 shows another embodiment of an example of arrangement of filters; and

FIGS. 12A, 12B and 12C show a plurality of modes of control of a group of pixels.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

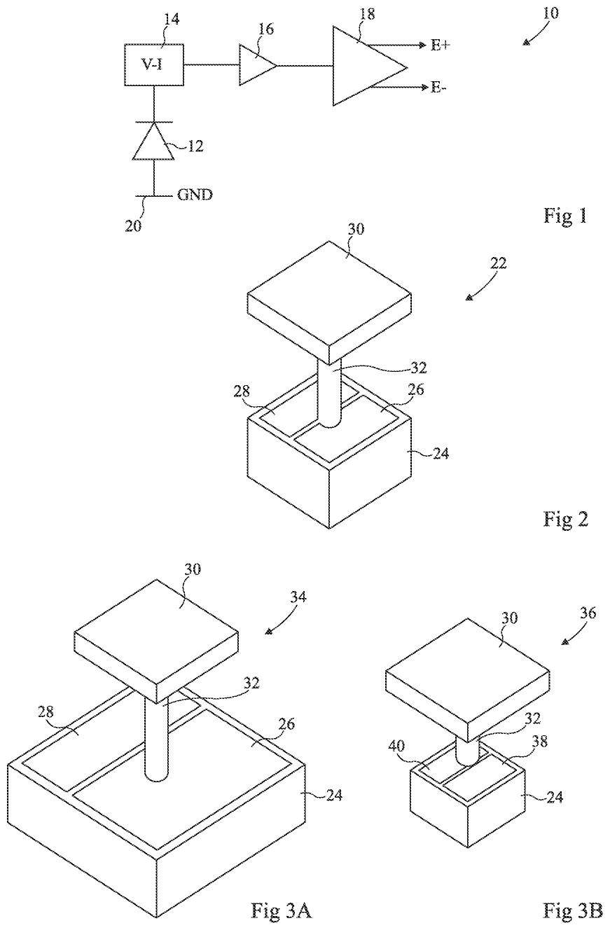

FIG. 1 schematically shows an example of a pixel 10 of an event-based camera, or neuromorphic camera.

Pixel 10 comprises a light detection element 12. Pixel 10 comprises, for example, a current-to-voltage converter 14. Pixel 10 comprises, for example, an amplifier 16. The pixel further comprises, for example, a comparator 18.

Converter 14 uses, for example, one or a plurality of transistors in subthreshold operation to perform a logarithmic conversion of the light intensity, enabling an extension of the dynamic operating range of the pixel. Amplifier 16 preferably enables amplification of the output voltage of converter 14 and to define a contrast threshold of the pixel. Comparator 18 preferably enables detection of whether the observed light variations differ from the contrast threshold, either positively, corresponding to an increase of the light intensity, or negatively, corresponding to a decrease of the light intensity.

Element 12 is, for example, a diode. Element 12 is, for example, coupled between a node 20 of application of a reference voltage, for example a voltage GND, and an input node of converter 14. For example, in the case where converter 14 captures electrons to transform the current into voltage, the anode of element 12 is coupled, for example preferably connected, to node 20 and the cathode of element 12 is coupled, for example preferably connected, to the input node of converter 14. For example, in the case where converter 14 captures holes to transform the current into voltage, the cathode of element 12 is coupled, for example preferably connected, to node 20 and the anode of element 12 is coupled, for example preferably connected, to the input node of converter 14. Converter 14 comprises an output coupled, for example preferably connected, to an input of amplifier 16. Amplifier 16 comprises an output coupled, for example preferably connected, to an input of comparator 18.

Comparator 18 is configured to deliver as an output information indicating that the light intensity measured by diode 12 has been modified. For example, comparator 18 comprises two outputs: a first output having a voltage E+ generated thereon and a second output having a voltage E− generated thereon. Voltages E+ and E− are, for example, binary signals. For example, voltage E+ takes a first value to indicate that the intensity measured by diode 12 has increased and a low value otherwise. For example, voltage E− takes a first value to indicate that the intensity measured on diode 12 has decreased and a low value otherwise. In the case of a synchronous camera, voltages E+ and E− are stored, for example, in memory cells, for example located at the output of the camera, which enables a periodic reading of the information generated by the comparator.

FIG. 2 shows an embodiment of a pixel 22 of an event-based camera. Pixel 22 corresponds, for example, to all or part of the pixel 10 illustrated in FIG. 1. The event-based camera comprises, for example, an array of pixels 22, for example only pixels 22.

Pixel 22 comprises a substrate 24. Substrate 24 is, for example, a semiconductor substrate. Electronic components are located inside and on top of substrate 24. More precisely, at least part of the components forming the control circuit of pixel 22 are located inside and on top of substrate 24. For example, the different components which enable operation to obtain the information indicating whether the measured intensity has varied are located, for example, inside and on top of substrate 24. For example, substrate 24 comprises converter 14, amplifier 16, and comparator 18.

For example, substrate 24 comprises a region 26 inside and on top of which are located analog components and a region 28 inside and on top of which are located logic components.

Pixel 22 further comprises a layer 30 comprising quantum dots (QD). Layer 30 forms the diode 12 of FIG. 1.

Layer 30 comprises quantum dots. The quantum dots of layer 30 are located, for example, in a layer made of a material other than a semiconductor material, for example made of an electrically-insulating material, for example made of a resin.

By quantum dot, there is meant that each quantum dot forms a confinement area by quantum effect in all dimensions, that is, in the three dimensions of space. Each quantum dot thus preferably has dimensions, in all directions, in the order of a few tens of nanometers, in other words smaller than 100 nm, preferably in the range from 2 nm to 15 nm.

Each quantum dot comprises a core made of a semiconductor material, for example made of lead sulfide. Said core preferably has dimensions in all directions in the order of a few tens of nanometers, in other words smaller than 100 nm. Each quantum dot further comprises ligands extending from the core. The ligands are preferably made of organic aliphatic molecules or metal-organic and inorganic molecules.

Due to their net charge and to their dipole moment, the ligands modify the effective doping of the layers of quantum dots as well as their electronic affinity. For example, the ligands of the quantum dots of layer 30 may be molecules acting as N-type dopants, for example organic molecules such as thiolates.

The materials forming the quantum dots and the dimensions of each quantum dot, in particular the dimensions of the semiconductor core, determine the absorption wavelengths of the quantum dots, that is, the operating wavelengths of the diode. The operating wavelengths for example correspond to near infrared, that is, wavelengths in the range from 700 nm to 1.6 mm. The operating wavelengths may also correspond to medium infrared, that is, wavelengths in the range from 1.6 μm to 4 μm or to the visible range, that is, wavelengths in the range from 300 nm to 700 nm.

It is possible to select an operating wavelength among a wider wavelength range than the wavelength range possible with a standard diode, that is, a diode comprising no quantum dot layer. Indeed, quantum dot layers correspond to an absorption curve having a peak significantly located on a wavelength, said wavelength depending on the materials of the quantum dot and being likely to be any wavelength of a wavelengths range comprising at least the wavelengths from 300 nm to 4 μm.

Pixel 22 further comprises a conductive via 32 coupling layer 30 to substrate 24. Via 32 crosses, for example, an electrically-insulating layer, not shown, separating layer 30 from substrate 24. Via 32 comprises, for example, one end in contact with layer 30 and another end coupled to the components located inside and on top of substrate 24, for example by an interconnection network covering substrate 24. Thus, via 32 for example couples layer 30, that is, the diode 12 of FIG. 1, and electric components, for example the converter 14 of FIG. 1, located inside and on top of substrate 24.

Thus, during the operation of pixel 22, the charges absorbed in layer 30 are attracted by via 32 and supplied to the components of substrate 24. More precisely, the charges located in a region surrounding the area of contact between the via and layer 30 are attracted by the via.

Event-based cameras are fast cameras. In other words, the cameras may reach a speed of 100,000 frames per second (fps), while standard cameras generally operate between 60 and 120 frames per second. Event-based cameras are thus adapted to the diodes formed by quantum dots, which may be slower than standard diodes due to the low mobility of the photosensitive layers given the transport mechanism (variable-distance jump).

FIGS. 3A and 3B show embodiments of pixels. More precisely, FIGS. 3A and 3B show a simplified comparison of a pixel 34 of an event-based camera (FIG. 3A) and of a pixel 36 of a standard camera (FIG. 3B).

Pixel 34 corresponds to pixel 22 of FIG. 2. Pixel 34 thus comprises quantum dot layer 30, via 32, and substrate 24 having the components forming the control circuit of the event-based camera pixel located therein.

Pixel 36 corresponds to a standard camera pixel. Pixel 36 comprises, like pixel 34, quantum dot layer 30 forming a diode, a via 32, and substrate 24. The substrate 24 of pixel 36 comprises a region 38 inside and on top of which are located analog components and a region 40 inside and on top of which are located logic components. The components located inside and on top of the substrate 24 of pixel 36, that is, the components located inside and on top of regions 38 and 40, form the control circuit of pixel 36.

The layers 30 and the vias 32 of pixels 34 and 36 are configured so that the regions of layer 30 where the charges are attracted towards via 32 have same dimensions, in particular a same surface area in top view. In other words, the portions of layer 30 associated with pixels 34 and 36 have the same dimensions.

The control circuit of pixel 36, that is, of a pixel of a standard camera, comprises less components than the control circuit of pixel 34, that is, of a pixel of an event-based camera. The regions of substrate 24 associated with pixel 34, that is, regions 26 and 28, thus have greater dimensions than the regions of substrate 24 associated with pixel 36, that is, regions 38 and 40.

Thus, as shown in FIGS. 3A and 3B, for regions of layer 30 where the charges are attracted towards the via 32 having the same surface area, the dimensions of the region of the substrate associated with pixel 34 are greater than the dimensions of the region of the substrate associated with pixel 36.

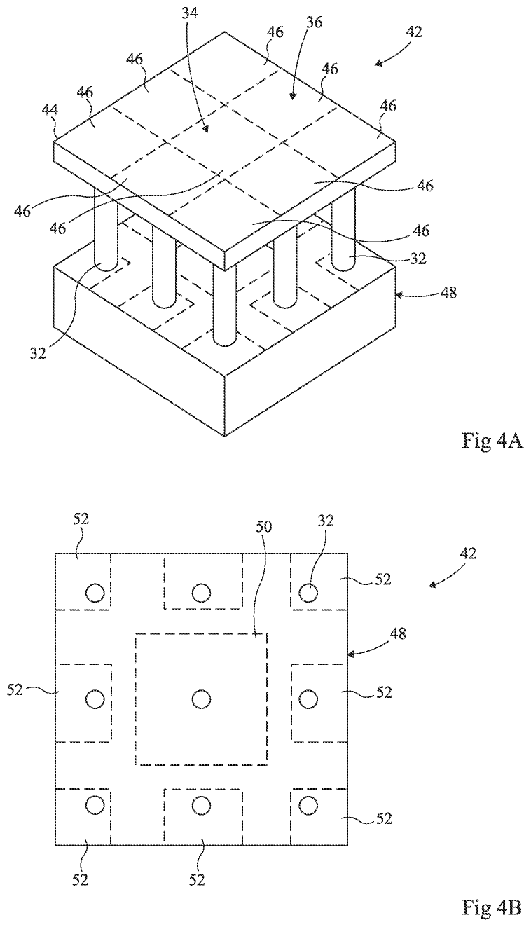

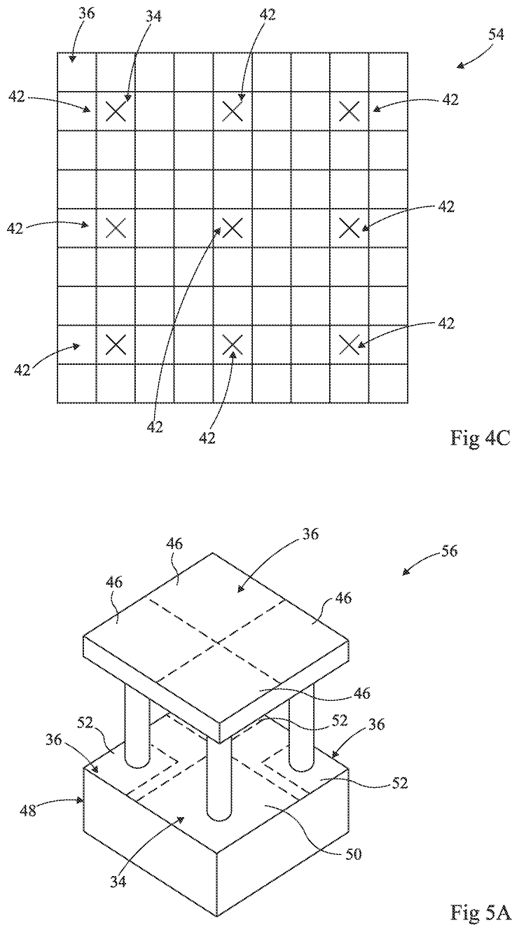

FIGS. 4A and 4B show an embodiment of an assembly 42 of pixels. FIG. 4A shows, in a perspective view, an embodiment of a pixel assembly. Figure shows a top view of a portion of the embodiment of FIG. 4A. More precisely, FIG. 4B shows a top view in a horizontal cross-section plane.

Assembly 42 corresponds, for example, to a portion of an image capture device, for example of a camera. Assembly 42 comprises at least one pixel 34 and at least one pixel 36, that is, at least one event-based camera pixel and at least one standard camera pixel. Assembly 42 thus enables the obtaining of event-based data and standard luminosity data.

In the example of FIGS. 4A and 4B, assembly 42 only comprises one pixel 34 and eight pixels 36. Pixel 34 is surrounded by pixels 36.

The pixels of assembly 42 comprise a common layer 44. Layer 44 corresponds to the layers 30 of each pixel 34 or 36. Layer 44 is thus formed of an array of regions 46, each region 46 forming part of a pixel and corresponding to the layer 30 described in relation with FIGS. 2 and 3. Preferably, layer 44 is entirely formed of regions 46. Thus, regions 46 are preferably not separated from regions which do not form part of a pixel.

Layer 44 is preferably continuous. The regions 46 of neighboring pixels are preferably in contact and are preferably not separated. Layer 44 preferably has a substantially constant thickness. Layer 44 is preferably homogeneous, that is, made of the same material over the entire surface. Regions 46 are preferably substantially identical to one another. Regions 46 are preferably parallelepipedal, for example having a rectangular surface, for example square, in top view. Layer 44 preferably comprises substantially identical quantum dots all over the surface of the layer. In other words, the quantum dots of layer 44 are preferably made of the same materials over the entire surface. Preferably, the density of quantum dots is identical (i.e., uniform) over the entire surface. Preferably, regions 46 all have the same dimensions.

Pixel 34 is surrounded by pixels 36. The region 46 corresponding to pixel 34 is thus surrounded by regions 46 corresponding to pixels 36.

Assembly 42 comprises a substrate 48, preferably a single substrate. Substrate 48 corresponds to the substrates 24 of pixels 34 and 36. Substrate 42 comprises all the regions 26 and 28 of pixel 34 and the regions 38 and 40 of pixels 36. Substrate 48 comprises regions 50, corresponding to the substrate 24 of pixel 34 and regions 52 corresponding to the substrates 24 of pixels 36. Thus, in FIGS. 4A and 4B, region 50 is surrounded by regions 52.

As explained in relation with FIGS. 3A and 3B, each region 52 has a surface area, for example in top view of substrate 48, for example in the plane of FIG. 4B, for example in a plane parallel to layer 44, smaller than the surface area of region 50, in the same plane. Preferably, the surface areas of regions 52 are equal to one another. In the example of FIGS. 4A and 4B, regions 50 and 52 are separated from one another by regions of substrate 48 which do not form part of a region 50 or of a region 52. However, according to another embodiment, regions 50 and 52 may be in contact. As a variant, region 50 may extend between at least certain regions 52.

Preferably, the region 46 of a pixel 34 has a surface area smaller than the surface area of region 50 in a plane parallel to the plane of layer 44, for example in the upper plane of substrate 48, that is, the plane of the surface of substrate 48 closest to layer 44. Preferably, the region 46 of a pixel 36 has a surface area greater than the surface area of region 52 in a plane parallel to the plane of layer 44, for example in the upper plane of substrate 48, that is, the plane of the surface of substrate 48 closest to layer 44. In other words, the region 50 of substrate 48 comprises portions which do not face region 46 of pixel 34. Said portions face portions of regions 46 of pixels 36. Thus, portions of the regions 46 of pixels 36 are not located in front of the regions 52 of the corresponding pixel.

Assembly 42 further comprises vias 32. Each pixel 34 or 36 comprises a via 32. Each via 32 extends from layer 44, more precisely from the region 46 corresponding to the pixel, to substrate 48, more precisely to the region 50 or 52 corresponding to the pixel. Vias 32 cross, for example, an insulating layer, not shown, extending between layer 44 and substrate 48.

Vias 32 preferably form an array of vias 32. Thus, vias 32 form rows and columns, corresponding to the rows and to the columns of the pixel array. The vias 32 of a same row or of a same column are preferably separated two by two by the same distance.

Each via 32 is preferably located at the center of the region 46 of the corresponding pixel. The via of a pixel is, for example, not located at the center of region 50 or 52 of substrate 48.

Each region 46 corresponds, for example, to the region where the corresponding pixel recovers the charges. In other words, during the operation of the device, charges are generated in layer 44. The charges generated in a region 46 are attracted by the via 32 of the pixel corresponding to region 46. Preferably, any charge generated in layer 44 is contained in a region 46 and is thus attracted by a via 32 to be processed by the pixel control circuit.

The dimensional differences of regions 50 and 52 enable to form arrays of identical regions 46, and in particular having identical dimensions. Indeed, the dimensions of regions 50 and 52 compensate for each other.

FIG. 4C shows a top view of a device 54 comprising the pixel assembly of FIG. 4A. More precisely, FIG. 4C shows a device 54 comprising a plurality of assemblies 42 such as described in relation with FIGS. 4A and 4B. For example, FIG. 4C shows a display of a camera configured to deliver an event-based image and a light intensity image.

Device 54 comprises an array of assemblies 42. Device 54 thus comprises a plurality, nine in FIG. 4C, of assemblies 42 arranged in rows and in columns. In other words, device 54 comprises rows and columns of assemblies 42, that is, of pixels 34 (shown by a square containing a cross) surrounded by eight pixels 36. In other words, device 54 comprises an alternation of, on the one hand, two columns only comprising pixels 36 and, on the other hand, a column comprising pixels 34 separated from one another by two pixels 36. Similarly, device 54 comprises an alternation of, on the one hand, two rows only comprising pixels 36 and, on the other hand, of a row comprising pixels 34 separated from one another by two pixels 36.

In device 54, the event-based image is thus obtained by an array of pixels 34. The pixels 34 of said array are separated from one another by a distance corresponding to two pixels 36.

In device 54, the light intensity image is obtained by an array of pixels 36. The array of pixels 36 is incomplete, certain pixels being separated from a neighboring pixel 36 of a same row or of a same column by a distance different from the distance separating them from other neighboring pixels 36. This is caused by the presence of pixels 34. The light intensity value of the location of pixels 34 is obtained by interpolation, for example by calculation of the average of the light intensities of the pixels 36 of the assembly 42 comprising the corresponding pixel 34.

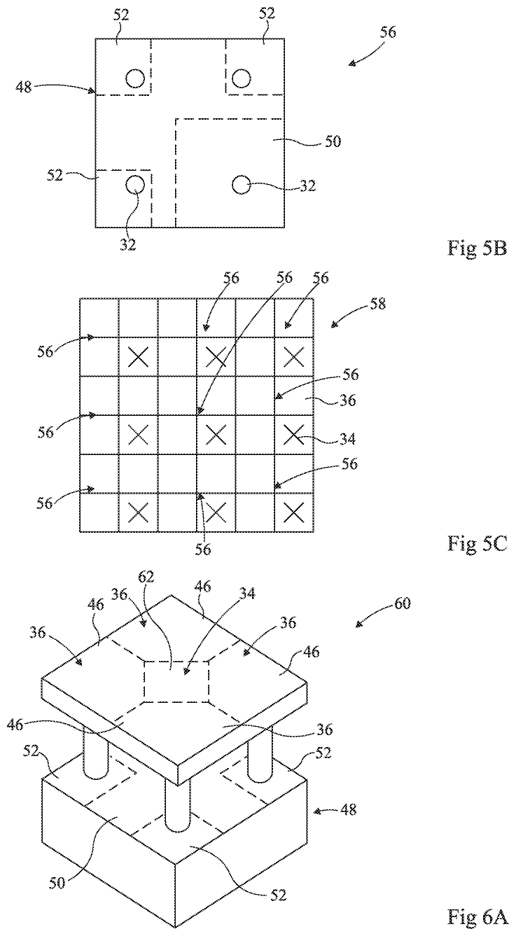

FIG. 5A shows, in a perspective view, another embodiment of an assembly 56 of pixels. FIG. 5B shows a top view of a portion of the embodiment of FIG. 5A.

The assembly 56 of FIGS. 5A and 5B differs from the assembly 42 of FIGS. 4A and 4B in that assembly 56 only comprises four pixels, among which one pixel 34 and three pixels 36. Pixels 34 and 36 correspond to the pixels described in relation with FIG. 3 and are such as described in relation with FIG. 3. Pixels 34 and 36 form, as in FIGS. 4A and 4B, an array. Said array comprises two rows and two columns. Said array thus comprises a row of two pixels 36 and a row comprising one pixel 34 and one pixel 36.

Assembly 56 comprises, like assembly 42, layer 44 common to pixels 34 and 36. Layer 44 corresponds to the layers 30 of each pixel 34 or 36. Layer 44 is thus formed of an array of regions 46, each region 46 forming part of a pixel and corresponding to the layer 30 described in relation with FIGS. 2 and 3A-3B. Layer 44, and regions 46, are such as described in relation with FIGS. 4A and 4B.

Like assembly 42, assembly 56 further comprises a substrate 48, preferably a single substrate, comprising the substrate regions of pixels 34 and 36. Further, assembly 56 comprises an array of vias 32, each via corresponding to the via 32 of a pixel 34 or 36. Vias 32 are arranged as described in relation with FIGS. 4A and 4B.

As in the embodiment of FIGS. 4A and 4B, regions 46 preferably have identical dimensions. Preferably, the region 46 of a pixel 34 has a surface area smaller than the surface area of region 50 in a plane parallel to the plane of layer 44, for example in the upper plane of substrate 48, that is, the plane of the surface of substrate 48 closest to layer 44. Preferably, the region 46 of a pixel 36 has a surface area greater than the surface area of region 52 in a plane parallel to the plane of layer 44, for example in the upper plane of substrate 48, that is, the plane of the surface of substrate 48 closest to layer 44. In other words, the region 50 of substrate 48 comprises portions which do not face the region 46 of pixel 34. Said portions face portions of the regions 46 of pixels 36. Thus, portions of the regions 46 of pixels 36 are not located in front of the regions 52 of the corresponding pixel.

As in the embodiment of FIGS. 4A and 4B, it is thus possible to form an array of identical regions 46, the dimensions of regions 50 and 52 compensating for each other.

FIG. 5C shows a top view of a device comprising the pixel assembly of FIG. 5A.

More precisely, FIG. 5C shows a device 58 comprising a plurality of assemblies 56 such as described in relation with FIGS. 5A and 5B. For example, FIG. 5C shows a display of a camera configured to deliver an event-based image and a light intensity image.

Device 58 comprises an array of assemblies 56. Device 58 thus comprises a plurality, nine shown in FIG. 5C, of assemblies 56 arranged in rows and in columns. In other words, device 58 comprises rows and columns of assemblies 56, that is, of pixels 34 (represented by a square containing a cross) in a corner of a square of four pixels, the three other pixels being pixels 36. Preferably, pixel 34 always corresponds to the same corner of assembly 56. In other words, device 58 comprises an alternation of a column only comprising pixels 36 and of a column comprising pixels 34 separated from one another by a pixel 36. Similarly, device 58 comprises an alternation of a row only comprising pixels 36 and of a row comprising pixels 34 separated from one another by a pixel 36.

In device 58, the event-based image is thus obtained by an array of pixels 34. The pixels 34 of said array are separated from one another by a distance corresponding to a pixel 36.

In device 58, the light intensity image is obtained by an array of pixels 36. The array of pixels 36 is incomplete, certain pixels being separated from a neighboring pixel 36 of a same row or of a same column by a distance different from the distance separating them from other neighboring pixels 36. This is caused by the presence of pixels 34. The light intensity value of the location of pixels 34 is obtained by interpolation, for example by calculation of the average of the light intensities of the pixels 36 surrounding the corresponding pixel 34.

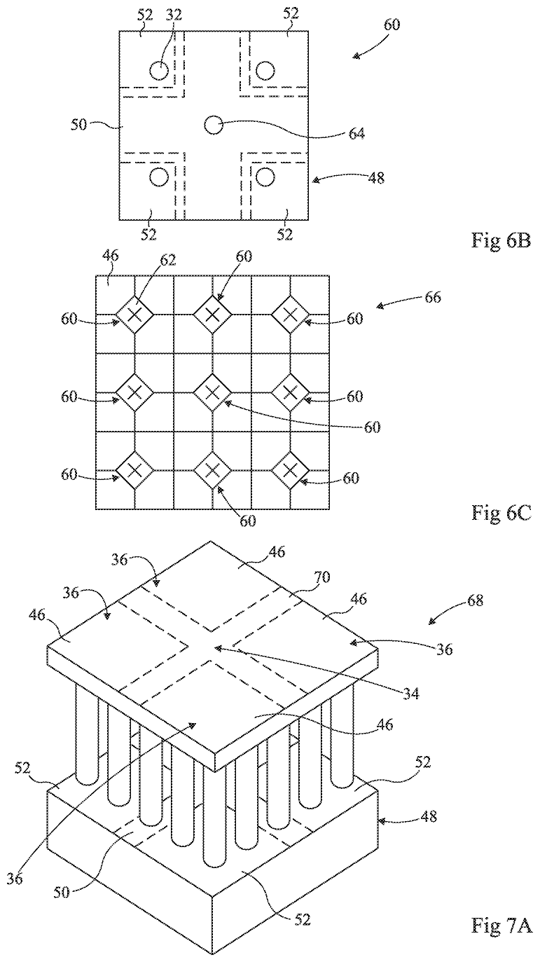

FIG. 6A shows, in a perspective view, another embodiment of an assembly 60 of pixels. FIG. 6B shows a top view of a portion of the embodiment of FIG. 6A.

The assembly 60 of FIGS. 6A and 6B differs from the assembly 56 of FIGS. 5A and 5B in that assembly 60 only comprises five pixels, among which one pixel 34 and four pixels 36. Pixels 34 and 36 correspond to the pixels described in relation with FIG. 3 and are such as described in relation with FIG. 3. Pixels 36 form an array. Said array comprises two rows and two columns of pixels 36. Pixels 36 surround pixel 34. In other words, pixel 34 is located at the center of assembly 60.

Assembly 60 comprises, like assembly 56, layer 44 common to pixels 34 and 36. Layer 44 corresponds to the layers 30 of each pixel 34 or 36. Layer 44 is thus formed of an array of regions 46, each region 46 forming part of a pixel 36. The layer 44 of assembly 60 further comprises a region 62 corresponding to the layer 30 of pixel 34. Layer 44, and regions 46, 62, are such as described in relation with FIGS. 4A and 4B. Regions 46 have, for example, a surface area smaller than the surface area of the regions 46 of assemblies 42 and 56. Regions 46 have the shape of a rectangle, preferably a square, having a beveled corner. The beveled corners of the four regions face the same point, that is, the center of the assembly so that the portions of layer 44 located at the center of the assembly, between the beveled corners, form region 62. Thus, regions 46 comprise, in the direction of the rows of pixels 36, two parallel sides, one being shorter than the other, the short sides being in contact with each other. Similarly, regions 46 comprise, in the direction of the columns of pixels 36, two parallel sides, one being shorter than the other, the short sides being in contact with each other. Each region 46 further comprises a side coupling the shortest sides of said region 46, said side corresponding to a side of region 62. Region 62 thus is a quadrilateral in top view.

Like assembly 56, assembly 60 further comprises a substrate 48, preferably a single substrate, comprising the substrate regions 50, 52 of pixels 34 and 36. Preferably, regions 52 are located at the corners of assembly 60. Region 50 is located between regions 50. Region 50 thus forms a cross separating regions 52 from one another.

Further, assembly 56 comprises an array of vias 32, each via corresponding to the via 32 of a pixel 36. Assembly 60 thus comprises complete rows and columns of vias 32 corresponding to pixels 36. Assembly further comprises vias 64 corresponding to the vias 32 of pixel 34. Via 64 extends between the region 62 of layer 44 and substrate 48, in particular region 50, preferably the middle of the cross.

As in the embodiment of FIGS. 5A and 5B, regions 46 preferably have identical dimensions and regions 62 have identical dimensions. Preferably, the region 62 of a pixel 34 has a surface area smaller than the surface area of region 50 in a plane parallel to the plane of layer 44, for example in the upper plane of substrate 48, that is, the plane of the surface of substrate 48 closest to layer 44. Preferably, the region 46 of a pixel 36 has a surface area greater than the surface area of region 52 in a plane parallel to the plane of layer 44, for example in the upper plane of substrate 48, that is, the plane of the surface of substrate 48 closest to layer 44. In other words, region 50 of substrate 48 comprises portions which do not face region 62 of pixel 34, for example the branches of the cross. Said portions face portions of regions 46 of pixels 36. Thus, portions of regions 46 of pixels 36 are not located in front of regions 52 of the corresponding pixel.

FIG. 6C shows a top view of a device 66 comprising the assembly 60 of pixels of FIG. 6A. More precisely, FIG. 6C shows a device 66 comprising a plurality of assemblies 60 such as described in relation with FIGS. 6A and 6B. For example, FIG. 6C shows a display of a camera configured to deliver an event-based image and a light intensity image.

Device 66 comprises an array of assemblies 60. Device 66 thus comprises a plurality, nine in FIG. 6C, of assemblies 60 arranged in rows and in columns. In other words, device 66 comprises rows and columns of assemblies 60, that is, of pixels 34 (represented by a box containing a cross), each surrounded by four pixels 36.

In device 66, the event-based image is thus obtained by an array of pixels 34. The pixels 34 of said array are separated from one another by a distance corresponding to two pixels 36.

In device 66, the light intensity image is obtained by an array of pixels 36. The array of pixels 36 is complete, each pixel 36 being at a same distance from all the neighboring pixels 36. No interpolation is thus necessary.

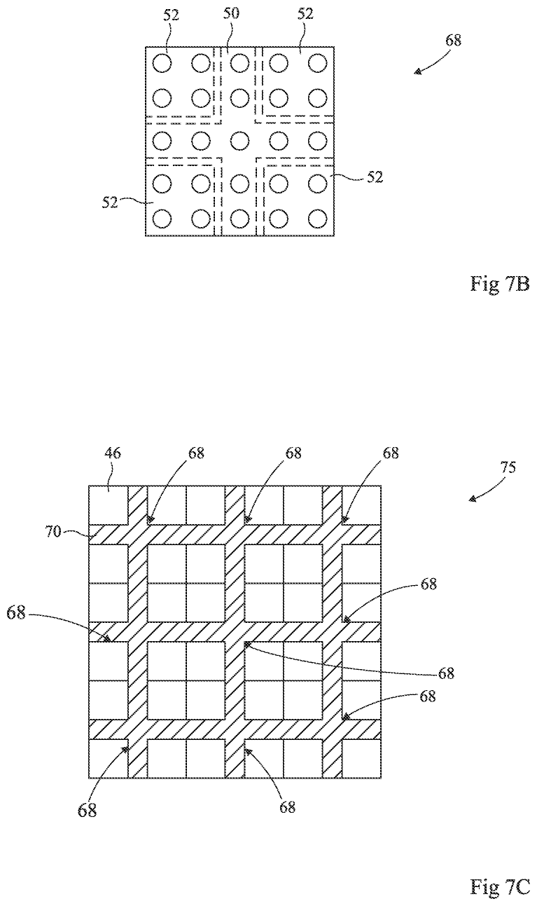

FIG. 7A shows, in a perspective view, another embodiment of an assembly 68 of pixels. FIG. 7B shows a top view of a portion of the embodiment of FIG. 7A.

The assembly 68 of FIGS. 7A and 7B differs from the assembly 56 of FIGS. 5A and 5B in that assembly 68 only comprises five pixels, among which one pixel 34 and four pixels 36. Pixels 34 and 36 correspond to the pixels described in relation with FIG. 3 and are such as described in relation with FIG. 3. Pixels 36 form an array. Said array comprises two rows and two columns of pixels 36. Pixels 36 surround pixel 34. In other words, pixel 34 is located at the center of assembly 68.

Assembly 68 comprises, like assembly 56, layer 44 common to pixels 34 and 36. Layer 44 corresponds to the layers 30 of each pixel 34 or 36. Layer 44 is thus formed of an array of regions 46, each region 46 forming part of a pixel 36. The layer 44 of assembly 68 further comprises a region 70 corresponding to the layer 30 of pixel 34. Layer 44 is such as described in relation with FIGS. 4A and 4B.

Regions 46 are preferably, in top view, rectangular, for example square. Regions 46 are separated from one another by region 70. Region 70 is cross-shaped. Region 70 comprises a portion, for example substantially rectilinear in top view, extending in the column direction and separating the pixels 36 of different columns. Region 70 comprises another portion, for example substantially rectilinear in top view, extending in the row direction and separating the pixels 36 of different rows. Thus, regions 46 are located at the corners of layer 44 of assembly 68 and are separated from one another by the branches of the cross of region 70.

Like assembly 56, assembly 68 further comprises a substrate 48, preferably a single substrate, comprising the substrate regions 50, 52 of pixels 34 and 36. Preferably, regions 52 are located at the corners of assembly 68. Region 50 is located between regions 50. Region 50 thus forms a cross separating regions 52 from one another.

Further, assembly 56 comprises an array of vias 32, each via corresponding to a via 32 of a pixel 34 or 36. Assembly 68 thus comprises complete rows and columns of vias 32.

Assembly comprises in particular vias 32 corresponding to the vias 32 of pixel 34. Assembly comprises at least one line of vias 32 extending in the row direction of the array of pixels 36, vias 32 extending between the branch of region 70 extending in the row direction of the array of pixels 36 and the branch of region 50 extending in the row direction of the array of pixels 36. Similarly, the assembly comprises at least one line of vias 32 extending in the column direction of the array of pixels 36, vias 32 extending between the branch of region 70 extending in the column direction of the array of pixels 36 and the branch of region 50 extending in the column direction of the array of pixels 36. Thus, the vias 32 corresponding to pixel 34 enable to attract the charges generated in the entire region 70 of pixel 34.

Assembly further comprises vias 32 corresponding to the vias of pixels 36. For example, each region 52 is coupled to the corresponding region 46 by at least one via 32. Preferably, the vias 32 corresponding to pixels 36 are arranged to form an array with the vias 32 corresponding to pixel 34.

As in the embodiment of FIGS. 5A and 5B, regions 46 preferably have identical dimensions. Preferably, the region 70 of a pixel 34 has a surface area smaller than the surface area of region 50 in a plane parallel to the plane of layer 44, for example in the upper plane of substrate 48, that is, the plane of the surface of substrate 48 closest to layer 44. Preferably, the region 46 of a pixel 36 has a surface area greater than the surface area of region 52 in a plane parallel to the plane of layer 44, for example in the upper plane of substrate 48, that is, the plane of the surface of substrate 48 closest to layer 44. In other words, the region 50 of substrate 48 comprises portions which do not face the region 70 of pixel 34, for example the branches of the cross. Said portions face portions of regions 46 of pixels 36. Thus, portions of regions 46 of pixels 36 are not located in front of the regions 52 of the corresponding pixel.

FIG. 7C shows a top view of a device 75 comprising the assembly 68 of pixels of FIG. 7A. More precisely, FIG. 7C shows a device 75 comprising a plurality of assemblies 68 such as described in relation with FIGS. 7A and 7B. For example, FIG. 7C shows a display of a camera configured to deliver an event-based image and a light intensity image.

Device 75 comprises an array of assemblies 68. Device 75 thus comprises a plurality, nine in FIG. 7C, of assemblies 68 arranged in rows and in columns. In other words, device 75 comprises rows and columns of assemblies 68, that is, of pixels 34 (shown by hatchings) each surrounded by four pixels 36.

Regions 70 form together a grid separating from one another groups of pixels 36. The groups of pixels comprise four pixels 36, pixels 36 belonging to different assemblies 68. Thus, the branches of regions 70 extending in the column direction of pixels 36 are separated two by two by two columns of pixels 36. Similarly, the branches of regions 70 extending in the row direction of pixels 36 are separated two by two by two rows of pixels 36.

In device 75, the event-based image is thus obtained by pixels 34 forming a grid extending on the assembly of the device. In the device 75, the light intensity image is obtained by an array of pixels 36. Although the regions 46 of certain neighboring pixels 36 are directly adjacent and the regions of other neighboring pixels 36 are separated by the region 70 of a pixel 34, this difference is relatively slight and thus no interpolation is necessary.

According to an embodiment, devices 54, 58, 66, and 75 can deliver an event-based image and a light intensity image independently. In other words, pixels 36 deliver, at a frame frequency, an image comprising a light intensity value, whatever the value provided by pixels 34. Further, each pixel 34 delivers event-based data, that is, indicating a modification of the light intensity measuring by pixel 34, independently from the values measured by pixels 36 and independently from the values provided by the other pixels 34.

According to another embodiment, pixels 36 are configured to generate a light intensity image when at least a number of pixels 34, for example at least one, measures a modification of the measured intensity. Thus, when the scene is modified, this is detected by pixels 34 and a light intensity image is generated by pixels 36.

According to another embodiment, the device is configured so that when a pixel 34 delivers event-based data indicating that the light intensity has changed, part of pixels 36, for example the neighboring pixels, for example the pixels surrounding pixel 34, provide a light intensity value. For example, in the case of device 54, said portion of pixels 36 corresponds to the pixels 36 of the assembly comprising pixel 34. The device thus delivers an event-based image and a light intensity image of the portion of the scene where there have been variations.

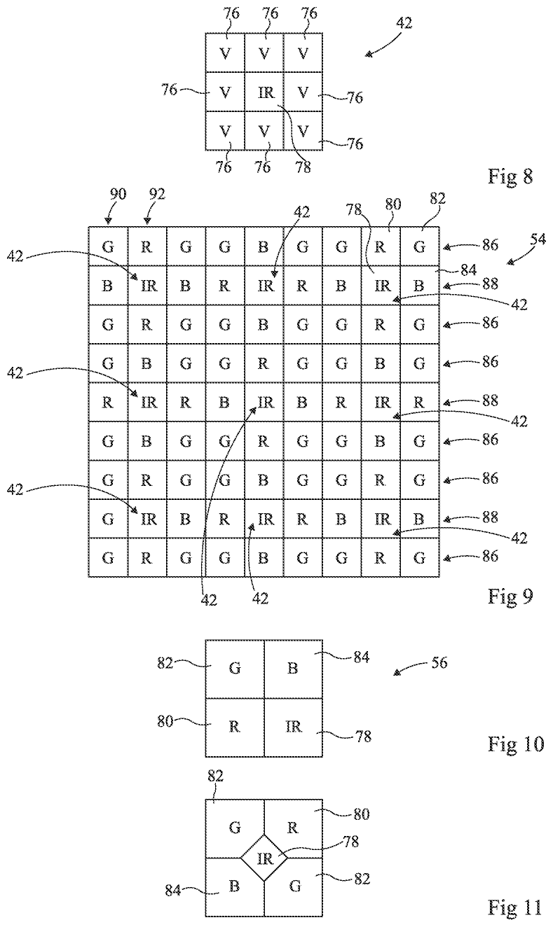

FIGS. 8 to 11 shows embodiments of arrangement of filters on certain pixels 34 and/or 36 of the previously-described embodiments. The filters are formed, for example, by a layer located on the region of layer 44 corresponding to certain pixels.

FIG. 8 shows an embodiment of an example of a filter arrangement. More precisely, FIG. 8 shows an embodiment of a filter arrangement on assembly 42.

According to the example of FIG. 8, pixels 36, and more precisely the regions 46 corresponding to pixels 36, are covered by a filter 76. Filters 76 are configured to let through wavelengths of the visible range (V), that is, wavelengths for example in the range from 0.4 μm to 0.7 μm, so that the signals having a wavelength in the infrared range create no noise in the pixel.

On the other hand, pixels 34, and more precisely the regions 46 corresponding to pixels 34, are covered by a filter 78. Filters 78 are configured, for example, to let through infrared wavelengths (IR), that is, wavelengths for example in the range from 0.7 μm to 100 μm. As a variant, filters 78 are for example configured to let through wavelengths in the range from 0.4 μm to 100 μm, to extend their photosensitive range.

FIG. 9 show another embodiment of an example of a filter arrangement. More precisely, FIG. 9 shows an embodiment of a filter arrangement on a device 54 comprising assemblies 42.

According to the example of FIG. 9, pixels 36, and more precisely the regions 46 corresponding to pixels 36, are covered by red filters (R) 80, green filters (G) 82, or blue filters (B) 84.

Filters 80 are configured to let through wavelengths corresponding to the red color, that is, wavelengths for example in the range from 622 nm to 780 nm. Filters 82 are configured to let through wavelengths corresponding to the green color, that is, wavelengths for example in the range from 492 nm to 577 nm. Filters 84 are configured to let through wavelengths corresponding to the blue color, that is, wavelengths for example in the range from 455 nm to 492 nm.

According to the embodiment of FIG. 9, each assembly 42 comprises, preferably, at least one pixel 36 associated with a filter 80, at least one pixel 36 associated with a filter 82, and at least one pixel 36 associated with a filter 84. In the example of FIG. 9, each assembly 42 comprises two pixels 36 associated with a filter 80, four pixels 36 associated with a filter 82, and two pixels 36 associated with a filter 84. Preferably, filters 82 are located at the corners of assembly 42. Preferably, filters 80 are located in front of each other, for example on the same row. Preferably, filters 84 are located in front of each other, for example on the same column.

On the other hand, pixels 34, and more precisely the regions 46 corresponding to pixels 34, are covered by filter 78. Filters 78 are configured to let through infrared wavelengths, that is, wavelengths for example in the range from 0.7 μm to 100 μm.

The device comprises an array of assemblies 42, each assembly 42 being arranged in such a way that the neighboring assemblies 42 of a same row or of a same column are rotated by 90° with respect to said assembly.

Device 54 preferably only comprises rows 86 and 88. Rows 86 comprise an alternation of pixels 36 associated with a filter 80 and of pixels 36 associated with a filter 84, each pixel 36 associated with a filter 80 is separated from each pixels 36 associated with a neighboring filter 84 by two pixels 36 associated with a filter 82. Each row 88 only comprises pixels 34 associated with filters 78, pixels 36 associated with filters 80, and pixels 36 associated with filters 84. In a row 88, each pixel 34 is located between two pixels 36 associated with filters 80 or between two pixels 36 associated with filters 84. In a row 88, each pixel 36 associated with a filter 80 is located between a pixel 34 associated with a filter 78 and a pixel 36 associated with a filter 84. In a row 88, each pixel 36 associated with a filter 84 is located between a pixel 34 associated with a filter 78 and a pixel 36 associated with a filter 80.

The array is preferably symmetrical. Thus, device 54 preferably only comprises columns 90 and 92. Columns 90 comprise an alternation of pixels 36 associated with a filter 80 and of pixels 36 associated with a filter 84, each pixel 36 associated with a filter 80 is separated from each pixel 36 associated with a filter neighboring 84 by two pixels 36 associated with a filter 82. Each column 92 only comprises pixels 34 associated with filters 78, pixels 36 associated with filters 80, and pixels 36 associated with filters 84. In a column 92, each pixel 34 is located between two pixels 36 associated with filters 80 or between two pixels 36 associated with filters 84. In a column 92, each pixel 36 associated with a filter 80 is located between a pixel 34 associated with a filter 78 and a pixel 36 associated with a filter 84. In a column 92, each pixel 36 associated with a filter 84 is located between a pixel 34 associated with a filter 78 and a pixel 36 associated with a filter 80.

FIG. 10 shows another embodiment of an example of a filter arrangement. More precisely, FIG. 10 shows an embodiment of a filter arrangement on an assembly 56.

Assembly 56 comprises three pixels 36 and one pixel 34. In the embodiment of FIG. 10, assembly 56 comprises a pixel 34 associated with a filter 78, that is, a filter only letting through infrared wavelengths, a pixel 36 associated with a filter 80, that is, a filter only letting through red wavelengths, a pixel 36 associated with a filter 82, that is, a filter only letting through green wavelengths, and a pixel 36 associated with a filter 84, that is, a filter only letting through blue wavelengths.

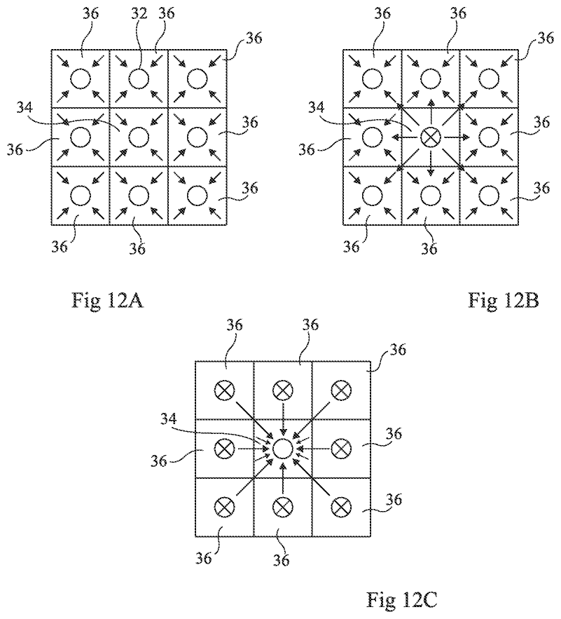

By the use of methods of controlling the pixels allowing the distribution of charges, described in relation with FIG. 12, the pixel 34 associated with a filter 78 may also collect part of the charges of the adjacent photodiodes. The loss of information relative to the color is then compensated for by the increase of the sensitivity of the event-based pixel.

FIG. 11 shows another embodiment of an example of a filter arrangement. More precisely, FIG. 11 shows an embodiment of a filter arrangement on assembly 60.

In the example of FIG. 11, pixels 34, and more precisely the regions 46 corresponding to pixels 34, are covered by filter 78. Further, each assembly 60 comprises a pixel 36 associated with a filter 80, two pixels 36 associated with a filter 82, and a pixel 36 associated with a filter 84. Preferably, the pixels 36 associated with filters 82 are located diagonally with respect to each other. In other words, the pixels 36 associated with filter 82 are preferably on different rows and columns.

FIGS. 12A, 12B and 12C show a plurality of modes of control of a pixel group.

More precisely, FIGS. 12A, 12B and 12C shows different modes of control of the group during a pixel readout step.

The control modes are described in relation with an assembly 42 of pixels such as that described in relation with FIGS. 4A to 4C. The control modes are however applicable to the pixels described in the previous drawings. Thus, although in FIGS. 12A, 12B and 12C the pixel assembly comprises one pixel 34 surrounded by eight pixels 36 belonging to the same assembly, the control modes are also applicable to groups of pixels comprising a pixel 34 surrounded by any number of pixels 36, for example four pixels 36, where pixels 36 may belong to different assemblies such as defined in relation with FIGS. 4A to 7C.

FIG. 12A shows a control mode during which each pixel 34 or 36 attracts towards its via 32 the charges (shown by arrows) generated in the region 46 corresponding to the pixel.

In the control mode corresponding to FIG. 12A, pixels 34 and 36 may operate simultaneously, the charge generation regions of the different pixels being separated and independent. As a variant, certain pixels may not be operating, that is, the via 32 of this pixel does not attract the charges located in region 46. The charges located in the region 46 of the pixels which are not operating are then lost and are not taken into account for the image generation.

FIGS. 12B and 12C show control modes where pixels 34 and pixels 36 are not operating at the same times. Thus, in the case of FIG. 12B, pixels 34 are not operating (shown by a cross) and in the case of FIG. 12C, pixels 36 are not operating.

In the case of FIG. 12B, the charges generated in region 46 of pixel 34 are attracted by the vias 32 of pixels 36 closest to the charge generation location. Thus, the charges generated in region 46 of pixel 34 are divided between the pixels 36 surrounding pixel 34.

In the case of FIG. 12C, the charges generated in region 46 of pixels 36 are attracted by the via 32 of the pixel 34 closest to the charge generation location. Thus, in the example of assembly 42 of FIGS. 4A to 4C, the charges generated in regions 46 of pixels 36 are attracted by the via 32 of the pixel 34 of the same assembly 42. As a variant, the charges are attracted by the vias 32 of the corresponding pixels 36 and then added, in the substrate, to the charges originating from the via 32 of pixel 34.

The distribution mode of FIG. 12C (or binning) enables increasing of the sensitivity of pixel 34 in support of increased operating speed as well as increased ability to detect events, while decreasing the associated noise.

The distribution of the charges photogenerated by a plurality of regions 46 may be achieved by a different biasing of the lower electrodes of the photodiodes of regions 46, in the case where the charges are attracted by the via of pixel 34, or by a specific routing and logic transistors at the level of the analog layer in the case where the charges are added in the substrate.

An advantage of the previously-described embodiments is that the device can deliver an event-based image and a light intensity image, for example non simultaneously, the event-based and standard pixels being readable independently.

Another advantage of the described embodiments is that a single substrate, comprising the pixel control circuits, is used. It is not necessary to have a second substrate for the diodes.

Another advantage of the described embodiments is that it is possible to form a complete display. In other words, charges may be generated all over the surface of the display. There is no area between pixels where charges cannot be generated.

Another advantage of the described embodiments is that, for a same number of pixels, the device can be smaller.

Another advantage of the described embodiments is that the possible wavelength range is larger.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A device, comprising:
a first pixel, based on quantum dots, configured to deliver event-based data for generating an event-based image; and
a plurality of second pixels, each second pixel based on quantum dots, configured to deliver light intensity data for generating a light intensity image.

2. The device according to claim 1, further comprising:
a quantum dot layer, where the first pixel comprises a first region of the quantum dot layer;
a substrate, wherein a second region of the substrate comprises a circuit for controlling the first pixel; and
a conductive via connecting the second region to the first region.

3. The device according to claim 2, wherein the second region comprises a portion located in front of the first region and a portion which is not in front of the first region.

4. The device or method according to claim 2, wherein each second pixel comprises a third region of the quantum dot layer; wherein a fourth region of the substrate comprises a circuit for controlling each second pixel; and a further conductive via connecting the fourth region to the third region.

5. The device according to claim 4, wherein the third region comprises a portion located in front of the fourth region and a portion which is not in front of the fourth region.

6. The device according to claim 1, wherein the first pixel is surrounded by the plurality of second pixels.

7. The device according to claim 1, wherein the event-based image is generated from event-based data independently from generation of the light intensity image from light intensity data.

8. The device according to claim 1, wherein the generation of event-based data by the first pixel triggers the generation of light intensity data by the plurality of second pixels.

9. The device according to claim 1, wherein the device includes an array of assemblies of pixels, wherein each assembly of pixels comprising one first pixel and eight second pixels surrounding the first pixel.

10. The device according to claim 9, wherein the first and third regions all have identical dimensions.

11. The device according to claim 1, wherein the device includes an array of assemblies of pixels, each assembly of pixels comprising one first pixel and three second pixels, arranged in an array.

12. The device according to claim 11, wherein the first and third regions all have identical dimensions.

13. The device according to claim 1, wherein the device includes an array of assemblies of pixels, each assembly pixels comprising one first pixel and four second pixels, each second pixel having the shape of a rectangle with a beveled corner, the beveled corners of the second pixels defining the first region of the first pixel.

14. The device according to claim 1, wherein the device includes an array of assemblies of pixels, each assembly of pixels comprising one first pixel and four second pixels, the first region of the first pixel having the shape of a cross separating the third regions of the second pixels from one another.

15. The device according to claim 1, further comprising an infrared filter covering the first pixel and visible wavelength range filter covering each second pixel.

16. A device, comprising:
a continuous layer including a surface covered by a plurality of substantially identical quantum dots having a uniform density;
wherein said continuous layer includes at least one array of regions, wherein the regions in said at least one array include at least one first region associated with a first pixel of an event-based camera configured to deliver event-based data for generating an event-based image and a plurality of second regions, adjacent the at least one first region, associated with second pixels of a luminosity camera configured to deliver light intensity data for generating a light intensity image.

17. The device of claim 16, further comprising a substrate, wherein the continuous layer is mounted over the substrate and electrically connected to circuitry in the substrate by vias.

18. The device of claim 17, wherein said circuitry includes first circuitry for controlling operation of the first pixel and second circuitry for controlling operation of the second pixels.

19. The device of claim 18, wherein the first circuitry occupies a first area of the substrate that is larger than an area of the continuous layer occupied by the first region.

20. The device of claim 19, wherein individual control circuits of the second circuitry for each of the second pixels occupies a second area of the substrate that is smaller than an area of the continuous layer occupied by a corresponding one of the second regions.
